(19) United States
(12) Patent Application Publication
(10) Pub. No.: US 2023/0326816 A1
(43) Pub. Date: Oct. 12, 2023

(54) SEMICONDUCTOR MODULE AND METHOD FOR MANUFACTURING THE SAME

(71) Applicant: FUJI ELECTRIC CO., LTD., Kawasaki-shi (JP)

(72) Inventor: Tadahiko SATO, Matsumoto-city (JP)

(73) Assignee: FUJI ELECTRIC CO., LTD., Kawasaki-shi (JP)

(21) Appl. No.: 18/323,925

(22) Filed: May 25, 2023

Related U.S. Application Data
(63) Continuation of application No. PCT/JP2022/010665, filed on Mar. 10, 2022.

(30) Foreign Application Priority Data
Jun. 23, 2021 (JP) 2021-104119

(51) Int. Cl. H01L 23/057; H01L 25/07; H01L 21/48; H01L 23/498; H01L 23/31; H01L 21/56

(52) U.S. Cl. CPC H01L 23/057; H01L 21/4853; H01L 21/56; H01L 23/3135; H01L 23/49811; H01L 25/072; H01L 24/48

(57) ABSTRACT

A semiconductor module includes: a semiconductor chip including a main electrode; a connection conductor electrically connected to the main electrode; a housing portion surrounding the semiconductor chip and at least a part of the connection conductor; a sealing material filled in a space surrounded by the housing portion; and a connection unit fixed to the housing portion. The conductive portion, which is a part of the connection conductor, is exposed from a surface of the sealing material. The connection unit includes: a connection terminal joined to the conductive portion of the connection conductor; and a support that is formed separately from the housing portion and supports the connection terminal.

### CROSS REFERENCE TO RELATED APPLICATIONS

This application is a Continuation Application of PCT Application No. PCT/JP2022/010665, filed on Mar. 10, 2022, and is based on and claims priority from Japanese Patent Application No. 2021-104119, filed on Jun. 23, 2021, the entire contents of each of which are incorporated herein by reference.

### BACKGROUND OF THE INVENTION

### Field of the Invention

The present disclosure relates to a semiconductor module and to a method for manufacturing the same.

### Description of Related Art

For example, various semiconductor modules including a semiconductor chip such as an insulated gate bipolar transistor (IGBT) have been conventionally proposed. For example, WO 2009/081723 A discloses a semiconductor module having a structure in which a semiconductor chip and a connection conductor are disposed in a frame-shaped terminal case. The connection conductor is a conductor directly or indirectly connected to the main electrode of the semiconductor chip. A connection terminal is installed in the terminal case by, for example, insert molding. The connection terminal protrudes inward from an inner wall surface of the terminal case. A space inside the terminal case is filled with a sealing material such as an epoxy resin. The top surface of the connection conductor is exposed from the surface of the sealing material. A portion of the connection terminal extending inward from the inner wall surface of the terminal case and the top surface of the connection conductor are joined to each other by, for example, laser welding.

In the technique of Patent Document 1, the connection terminal protrudes inward from the inner wall surface of the terminal case at the stage of filling the terminal case with the sealing material. That is, a part of the sealing material is positioned behind the connection terminal when viewed from above in the vertical direction. Therefore, it is not easy to, for example, visually confirm the state of the sealing material immediately below the connection terminal (for example, the state of adhesion to the inner wall surface of the terminal case).

### SUMMARY

In view of the above circumstances, an object of one aspect of the present disclosure is to make it possible to easily confirm a state of a sealing material for sealing a semiconductor chip in a process of manufacturing a semiconductor module.

In order to solve the above problem, a semiconductor module according to the present disclosure includes: a first semiconductor chip including a first main electrode; a connection conductor electrically connected to the first main electrode; a housing portion surrounding the first semiconductor chip and the connection conductor; a first sealing material filled in a space surrounded by the housing portion; and a connection unit fixed to the housing portion, in which a conductive portion is exposed from a surface of the first sealing material, the conductive portion being a part of the connection conductor, and the connection unit includes: a first terminal joined to the conductive portion of the connection conductor; and a support that is configured separately from the housing portion and supports the first terminal.

Furthermore, a method for manufacturing a semiconductor module according to the present disclosure includes: filling with a first sealing material a space inside a housing portion surrounding (i) a first semiconductor chip including a first main electrode and (ii) a connection conductor electrically connected to the first main electrode, such that a conductive portion that is a part of the connection conductor is exposed; and after execution of the filling with the first sealing material, fixing to the housing portion a connection unit including the first terminal and a support supporting the first terminal, and joining the conductive portion of the connection conductor and a first terminal.

### BRIEF DESCRIPTION OF THE DRAWINGS

FIG. 1 is a plan view of a semiconductor module according to a First Embodiment.

FIG. 2 is a cross-sectional view taken along line a-a in FIG. 1.

FIG. 3 is a plan view of a semiconductor module in a state in which a connection unit is separated.

FIG. 4 is a cross-sectional view of the semiconductor module in a state in which the connection unit is separated.

FIG. 5 is a process diagram illustrating a method for manufacturing a semiconductor module.

FIG. 6 is a cross-sectional view illustrating a configuration of Comparative Example 1.

FIG. 7 is a plan view of a semiconductor module according to a Second Embodiment.

FIG. 8 is a cross-sectional view taken along line b-b in FIG. 7.

FIG. 9 is an enlarged cross-sectional view of the vicinity of a protrusion.

FIG. 10 is an enlarged cross-sectional view of the vicinity of a support in the First Embodiment.

FIG. 11 is a partial cross-sectional view of a semiconductor module according to a Third Embodiment.

FIG. 12 is a partial cross-sectional view of a semiconductor module according to a Fourth Embodiment.

FIG. 13 is a partial cross-sectional view of a semiconductor module according to an aspect A of modification (1).

FIG. 14 is a partial cross-sectional view of a semiconductor module according to an aspect B of modification (1).

FIG. 15 is a partial cross-sectional view of a semiconductor module according to an aspect C of modification (2).

FIG. 16 is a cross-sectional view of a semiconductor module according to modification (3).

FIG. 17 is a cross-sectional view of a semiconductor module according to modification (5).

### DESCRIPTION OF THE EMBODIMENTS

Embodiments for carrying out the present disclosure will be described with reference to the drawings. Note that in each drawing, dimensions and scales of each element may be different from those of an actual product. The embodiments described below are specific examples assumed in a case in which the present disclosure is implemented. Therefore, the scope of the present disclosure is not limited to the following embodiments.

### A: First Embodiment

### A-1: Structure of Semiconductor Module 100

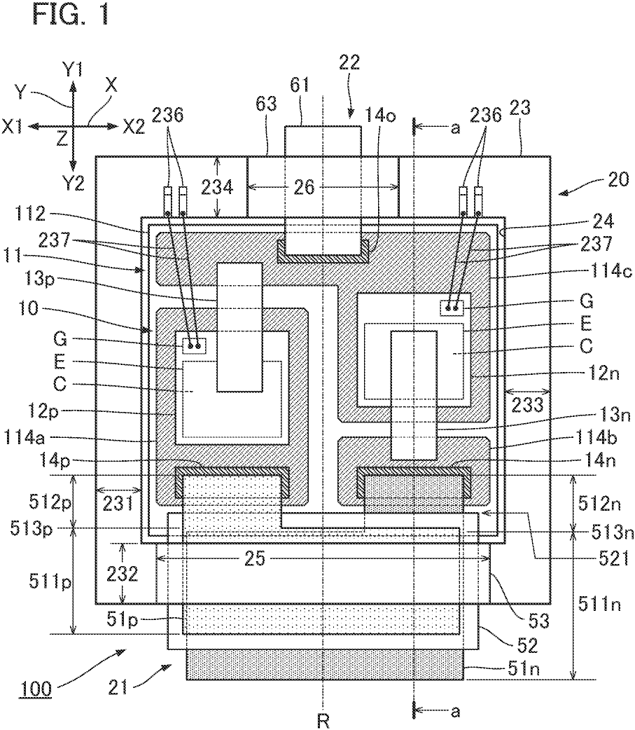

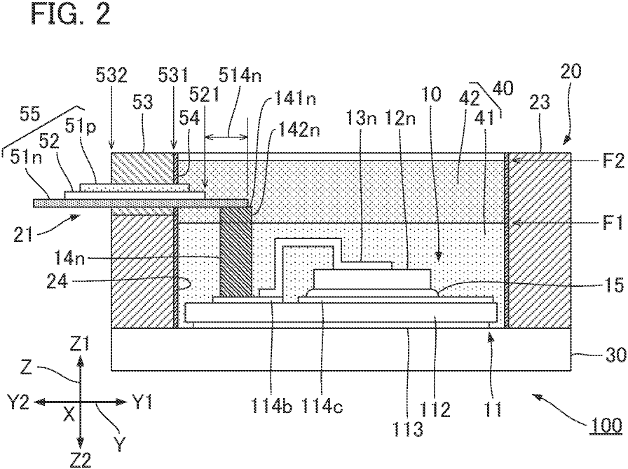

FIG. 1 is a plan view illustrating a configuration of a semiconductor module 100 according to a First Embodiment. FIG. 2 is a cross-sectional view taken along line a-a in FIG. 1. As illustrated in FIGS. 1 and 2, in the First Embodiment, an X axis, a Y axis, and a Z axis orthogonal to each other are assumed. One direction along the X axis is referred to as the X1 direction, and a direction opposite to the X1 direction is referred to as the X2 direction. One direction along the Y axis is referred to as the Y1 direction, and a direction opposite to the Y1 direction is referred to as the Y2 direction. Similarly, one direction along the Z axis is referred to as the Z1 direction, and a direction opposite to the Z1 direction is referred to as the Z2 direction. Visually recognizing an freely chosen element of the semiconductor module 100 along the Z axis direction (Z1 direction or Z2 direction) is hereinafter referred to as “in plan view”.

Note that although the semiconductor module 100 can be installed in any direction in an actual use, the Z1 direction is assumed to be upward and the Z2 direction is assumed to be downward, for convenience, in the following description. Therefore, a surface facing the Z1 direction among freely chosen elements of the semiconductor module 100 may be described as an “upper surface”, and a surface facing the Z2 direction among the elements may be described as a “lower surface”. As illustrated in FIG. 1, in the following description, a virtual plane (hereinafter referred to as a “reference surface”) R parallel to a YZ plane is assumed. The reference surface R is located at the center of the semiconductor module 100 along the X axis. That is, the reference surface R is a plane that divides the semiconductor module 100 into two halves along the X axis.

As illustrated in FIGS. 1 and 2, the semiconductor module 100 according to the First Embodiment includes a semiconductor unit 10, a housing body 20, a base portion 30, and a sealing portion 40. Note that in FIG. 1, the illustrations of the base portion 30 and the sealing portion 40 are omitted for convenience.

The base portion 30 is a structure that supports the semiconductor unit 10 and the housing body 20, and is formed of a conductive material such as aluminum or copper. For example, the base portion 30 is a heat sink. In addition, the base portion 30 may be a cooler such as a fin or a water cooling jacket for cooling the semiconductor unit 10. Furthermore, the base portion 30 may be used as a ground body set to ground potential.

The housing body 20 houses the semiconductor unit 10. Specifically, the housing body 20 is formed in a rectangular frame shape surrounding the semiconductor unit 10. That is, as illustrated in FIG. 2, the semiconductor unit 10 is housed in a space surrounded by the housing body 20 with the base portion 30 as a bottom surface. The sealing portion 40 seals the semiconductor unit 10 by being filled into the space inside the housing body 20. The sealing portion 40 is formed of various resin materials such as an epoxy resin or silicone gel. The sealing portion 40 may include various fillers such as silicon oxide or aluminum oxide.

As illustrated in FIGS. 1 and 2, the semiconductor unit 10 includes a laminated substrate 11, a semiconductor chip 12p, a semiconductor chip 12n, a wiring portion 13p, a wiring portion 13n, a connection conductor 14p, a connection conductor 14n, and a connection conductor 14o. Note that in the following description, an additional letter p is added to a reference sign of an element corresponding to the semiconductor chip 12p, and an additional letter n is added to a reference sign of an element corresponding to the semiconductor chip 12n. The semiconductor chip 12p and the semiconductor chip 12n will be simply referred to as the “semiconductor chip 12” when they need not be distinguished from each other (in a case in which the description is appropriate for both). The same applies to other elements.

The laminated substrate 11 is a plate-shaped member that supports each semiconductor chip 12 (12p, 12n), each wiring portion 13 (13p, 13n), and each connection conductor 14 (14p, 14n, 14o). For example, a laminated ceramic substrate such as a direct copper bonding (DCB) substrate or an active metal brazing (AMB) substrate, or a metal base substrate including a resin insulating layer is used as the laminated substrate 11.

As illustrated in FIG. 2, the laminated substrate 11 is formed by laminating an insulating substrate 112, a metal layer 113, and conductor patterns 114 (114a, 114b, 114c). The insulating substrate 112 is a rectangular plate-shaped member formed of an insulating material. The material of the insulating substrate 112 is selected as desired, and for example, a ceramic material such as alumina (Al₂O₃), aluminum nitride (AlN), or silicon nitride (Si₃N₄), or a resin material such as an epoxy resin is used. Note that the reference surface R is also expressed as a plane that divides the insulating substrate 112 into two halves along the X axis.

The metal layer 113 is a conductive film formed on a lower surface of the insulating substrate 112 facing the base portion 30. The metal layer 113 is formed in the entire region or a region (for example, a region other than the edge) of the lower surface of the insulating substrate 112. A lower surface of the metal layer 113 is in contact with an upper surface of the base portion 30. The metal layer 113 is formed of, for example, a metal material having high thermal conductivity such as copper or aluminum. The conductor patterns 114 (114a, 114b, 114c) are conductive films formed apart from each other on an upper surface of the insulating substrate 112 on the side opposite to the base portion 30. Each conductor pattern 114 is formed of a low-resistance conductive material such as copper or a copper alloy.

As illustrated in FIG. 1, the conductor pattern 114a is a conductive film having a rectangular shape formed in a region of the upper surface of the insulating substrate 112 in the X1 direction as viewed from the reference surface R. The conductor pattern 114b is a conductive film having a rectangular shape formed in a region of the upper surface of the insulating substrate 112 in the X2 direction as viewed from the reference surface R. The conductor pattern 114c is a conductive film formed in the Y1 direction as viewed from the conductor pattern 114a and the conductor pattern 114b. Specifically, the conductor pattern 114c is formed in a planar shape including a region located in the Y1 direction of the conductor pattern 114a and a region located in the Y1 direction of the conductor pattern 114b.

The semiconductor chips 12 (12p, 12n) are power semiconductor elements capable of switching a large current. Specifically, each semiconductor chip 12 may include a transistor such as an insulated gate bipolar transistor (IGBT) or a metal-oxide-semiconductor field-effect transistor (MOSFET), a reverse conducting IGBT (RC-IGBT), a freewheeling diode (FWD), and the like. The First Embodiment exemplifies a configuration in which the semiconductor chip 12 is an RC-IGBT including an IGBT portion and an FWD portion.

Each semiconductor chip 12 (12p, 12n) includes a main electrode E, a main electrode C, and a control electrode G. The main electrode E and the main electrode C are electrodes to which a current to be controlled is input or output. Specifically, the main electrode E is an emitter electrode formed on an upper surface of the semiconductor chip 12, and the main electrode C is a collector electrode formed on a lower surface of the semiconductor chip 12. The main electrode C also functions as an anode electrode of the FWD portion, and the main electrode E also functions as a cathode electrode of the FWD portion. On the other hand, the control electrode G is a gate electrode which is formed on the upper surface of the semiconductor chip 12 and to which a voltage is applied for controlling the turning On and OFF of the semiconductor chip 12. The control electrode G may include a detection electrode for current detection, temperature detection, or the like. The semiconductor chip 12n is an example of a “first semiconductor chip”, and the main electrode E of the semiconductor chip 12n is an example of a “first main electrode”. The semiconductor chip 12p is an example of a “second semiconductor chip”, and the main electrode C of the semiconductor chip 12p is an example of a “second main electrode”.

As illustrated in FIG. 2, the semiconductor chips 12 (12p, 12n) are joined to the laminated substrate 11 by using a joining material 15 such as solder. Specifically, as illustrated in FIG. 1, the semiconductor chip 12p is joined to the conductor pattern 114a. That is, the main electrode C of the semiconductor chip 12p is joined to the conductor pattern 114a. The semiconductor chip 12n is joined to the conductor pattern 114c of the laminated substrate 11. That is, the main electrode C of the semiconductor chip 12n is joined to the conductor pattern 114c.

The wiring portion 13p in FIG. 1 is wiring that electrically connects the main electrode E of the semiconductor chip 12p to the conductor pattern 114c. The wiring portion 13p extends along the Y axis. An end of the wiring portion 13p located in the Y2 direction is joined to the main electrode E of the semiconductor chip 12p, and an end of the wiring portion 13p located in the Y1 direction is joined to the conductor pattern 114c. On the other hand, the wiring portion 13n is wiring that electrically connects the main electrode E of the semiconductor chip 12n to the conductor pattern 114b. The wiring portion 13n extends along the Y axis. An end of the wiring portion 13n located in the Y1 direction is joined to the main electrode E of the semiconductor chip 12n, and an end of the wiring portion 13n located in the Y2 direction is joined to the conductor pattern 114b. The wiring portion 13p and the wiring portion 13n are lead frames formed of a low-resistance conductive material such as copper or a copper alloy.

The connection conductors 14 (14p, 14n, 14o) are formed of a low-resistance conductive material such as copper or a copper alloy. The connection conductor 14p is a conductor for electrically connecting the semiconductor chip 12p externally. Specifically, the connection conductor 14p is joined to the surface of the conductor pattern 114a with a joining material (not illustrated) such as solder. That is, the connection conductor 14p is electrically connected to the main electrode C of the semiconductor chip 12p via the conductor pattern 114a. The connection conductor 14p is located in the Y2 direction as viewed from the semiconductor chip 12p and the wiring portion 13p. As understood from the above description, the semiconductor chip 12p, the wiring portion 13p, and the connection conductor 14p are installed in the space in the X1 direction as viewed from the reference surface R.

The connection conductor 14n is a conductor for electrically connecting the semiconductor chip 12n externally. Specifically, the connection conductor 14n is joined to the surface of the conductor pattern 114b with a joining material (not illustrated) such as solder. That is, the connection conductor 14n is electrically connected to the main electrode E of the semiconductor chip 12n via the conductor pattern 114b and the wiring portion 13n. The connection conductor 14n is located in the Y2 direction as viewed from the semiconductor chip 12n and the wiring portion 13n. As understood from the above description, the semiconductor chip 12n, the wiring portion 13n, and the connection conductor 14n are installed in the space in the X2 direction as viewed from the reference surface R. The connection conductor 14p and the connection conductor 14n are arranged along the X axis at an interval.

The connection conductor 14o is a conductor for electrically connecting the conductor pattern 114c externally. Specifically, the connection conductor 14o is joined to the surface of the conductor pattern 114c with a joining material (not illustrated) such as solder. That is, the connection conductor 14o is electrically connected to the main electrode E of the semiconductor chip 12p via the conductor pattern 114c and the wiring portion 13p, and is electrically connected to the main electrode C of the semiconductor chip 12n via the conductor pattern 114c.

As illustrated in FIG. 2, each of the connection conductor 14p, the connection conductor 14n, and the connection conductor 14o is a columnar structure protruding in the Z1 direction from the laminated substrate 11. Each connection conductor 14 has a rectangular planar shape. That is, the connection conductor 14 of the First Embodiment has a prismatic shape. A top surface 141p of the connection conductor 14p, a top surface 141n of the connection conductor 14n, and a top surface of the connection conductor 14o are at higher positions than other elements of the semiconductor unit 10. That is, along the Z axis, the top surface 141 of each connection conductor 14 is positioned in the Z1 direction relative to the laminated substrate 11, the respective wiring portion 13, and the respective semiconductor chip 12.

The housing body 20 of FIG. 1 includes a connection unit 21, a connection unit 22, and a housing portion 23. The connection unit 21 and the connection unit 22 formed separately from the housing portion 23 are fixed to the housing portion 23, thereby forming the housing body 20.

The housing portion 23 is a frame-shaped structure in plan view, and surrounds the semiconductor unit 10. That is, the semiconductor unit 10 is housed in the space surrounded by the housing portion 23. Specifically, a lower surface of the housing portion 23 is joined to an edge of the upper surface of the base portion 30 with, for example, an adhesive. The semiconductor unit 10 is housed in the housing portion 23 with side surfaces of the laminated substrate 11 (insulating substrate 112) facing inner wall surfaces of the housing portion 23 at intervals. That is, each semiconductor chip 12 (12p, 12n) and each wiring portion 13 (13p, 13n) are surrounded by the housing portion 23. At least a part of each of the connection conductors 14 (14p, 14n, 14o) including the lower end is also surrounded by the housing portion 23. Note that the inner wall surfaces of the housing portion 23 are wall surfaces (inner peripheral surfaces) facing the center of the housing portion 23 in plan view. The housing portion 23 is formed of various resin materials such as a polyphenylene sulfide (PPS) resin, a polybutylene terephthalate (PBT) resin, a polybutylene succinate (PBS) resin, a polyamide (PA) resin, or an acrylonitrile-butadiene-styrene (ABS) resin. The housing portion 23 may include a filler formed of an insulating material.

Specifically, as illustrated in FIG. 1, the housing portion 23 is a structure having a rectangular frame shape in which a side wall 231, a side wall 232, a side wall 233, and a side wall 234 are connected to each other in the above order. The side wall 231 and the side wall 233 are side walls extending along the Y axis at a predetermined interval along the X axis. On the other hand, the side wall 232 and the side wall 234 are side walls extending along the X axis at a predetermined interval along the Y axis. The side wall 232 and the side wall 234 are shaped to connect the ends of the side wall 231 and the side wall 233 to each other. The connection conductor 14p and the connection conductor 14n of the semiconductor unit 10 are arranged at an interval along the side wall 232 and at positions spaced apart in the Y1 direction from the inner wall surface of the side wall 232.

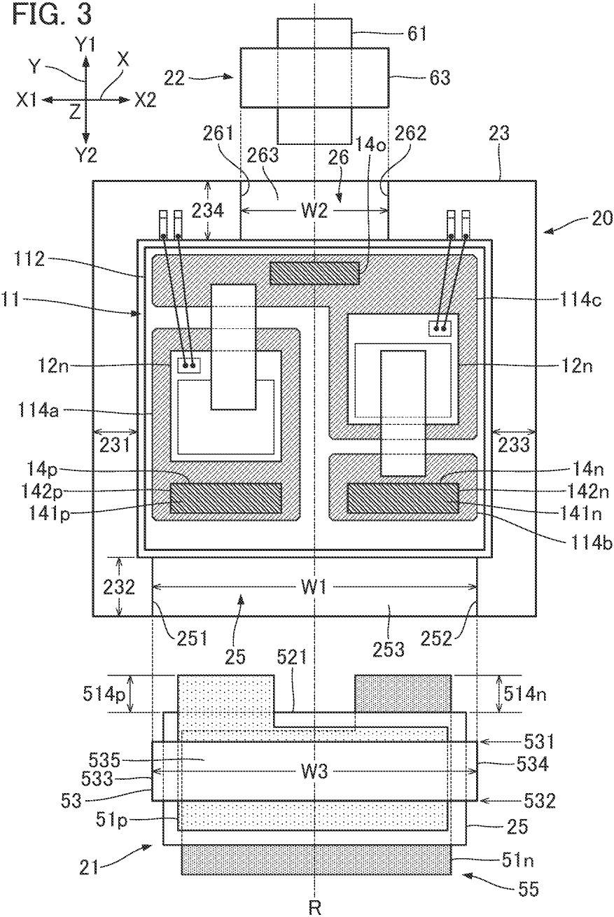

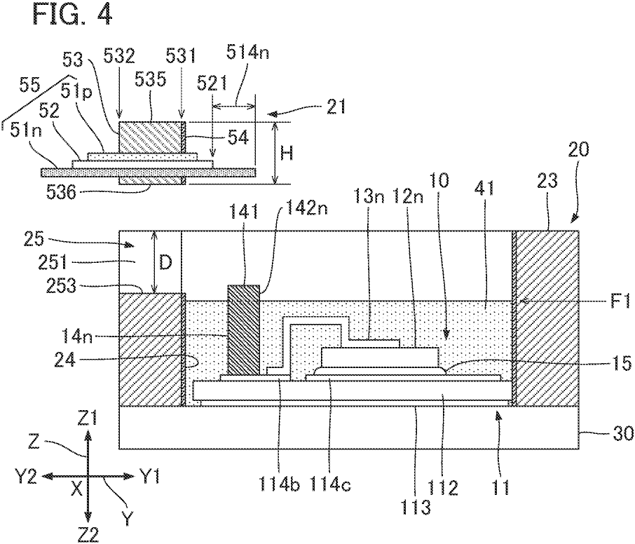

FIGS. 3 and 4 illustrate a state in which the connection unit 21 and the connection unit 22 are separated from the housing portion 23. As illustrated in FIGS. 3 and 4, a recess 25 is formed in the side wall 232 of housing portion 23. The recess 25 is a recess formed in a part of the upper surface of the side wall 232 and is open in the Z1 direction. The recess 25 is a space in which the connection unit 21 is accommodated. The recess 25 of the First Embodiment penetrates the side wall 232 along the Y axis. Specifically, the recess 25 is a rectangular parallelepiped space defined by a side surface 251 and a side surface 252 facing each other at an interval along the X axis, and a bottom surface 253 located at a lower position than the upper surface of the side wall 232. The side surface 251 and the side surface 252 are planes parallel to the YZ plane, and the bottom surface 253 is a plane parallel to the XY plane.

On the other hand, a recess 26 is formed in the side wall 234 of the housing portion 23. The recess 26 is a recess formed in a part of the upper surface of the side wall 234 and opened in the Z1 direction. The recess 26 is a space in which the connection unit 22 is accommodated. The recess 26 of the First Embodiment penetrates the side wall 234 along the Y axis. Specifically, the recess 26 is a rectangular parallelepiped space defined by a side surface 261 and a side surface 262 facing each other at an interval along the X axis, and a bottom surface 263 located at a lower position than the upper surface of the side wall 234. The side surface 261 and the side surface 262 are planes parallel to the YZ plane, and the bottom surface 263 is a plane parallel to the XY plane.

A lateral width W1 in FIG. 3 is a dimension of the recess 25 along the X axis (that is, an interval between the side surface 251 and the side surface 252), and a lateral width W2 is a dimension of the recess 26 along the X axis (that is, a distance between the side surface 261 and the side surface 262). The lateral width W1 of the recess 25 exceeds the lateral width W2 of the recess 26 (W1 > W2).

As illustrated in FIG. 1, control terminals 236 are installed on the side wall 234 of the housing portion 23. The control terminals 236 are lead terminals for electrically connecting the control electrodes G of the respective semiconductor chips 12 externally, and are formed integrally with the housing portion 23 by, for example, insert molding. Each control terminal 236 is electrically connected to the control electrode G of the corresponding semiconductor chip 12 (12p, 12n) by, for example, wires 237.

As illustrated in FIG. 2, a base film 24 is formed on the inner wall surface of the housing portion 23. The base film 24 is a film body that covers the inner wall surface of the housing portion 23. The base film 24 functions as a primer for improving adhesion of the sealing portion 40 to the inner wall surface of the housing portion 23. An appropriate resin material corresponding to the material of the housing portion 23 and the material of the sealing portion 40 is used for forming the base film 24. Specifically, the base film 24 is formed of, for example, a silane coupling agent. The base film 24 may be formed of, for example, a polyimide resin, a polyamideimide resin, a polyamide resin, or their modified products. Note that in FIG. 1, the illustration of the base film 24 is omitted for convenience.

As illustrated in FIGS. 3 and 4, the connection unit 21 includes a support 53 and a terminal portion 55. The support 53 is a structure that supports the terminal portion 55. Similarly to the housing portion 23, the support 53 is formed of various resin materials such as a PPS resin, a PBT resin, a PBS resin, a PA resin, and an ABS resin. In a more preferred aspect, the support 53 is formed of the same type of material as the housing portion 23. The connection unit 21 is integrally formed by, for example, insert molding.

The support 53 is a rectangular parallelepiped structure including an inner wall surface 531 and an outer wall surface 532, a side surface 533 and a side surface 534, and an upper surface 535 and a lower surface 536. The inner wall surface 531 is a side surface facing the Y1 direction (inner side of the housing body 20), and the outer wall surface 532 is a side surface facing the Y2 direction (outer side of the housing body 20). A base film 54 is formed on the inner wall surface 531 of the support 53 in the same manner as the inner wall surface of the housing portion 23. The base film 54 functions as a primer for improving adhesion between the inner wall surface 531 of the support 53 and the sealing portion 40 (sealing material 42). However, the base film 54 may be omitted.

The side surface 533 is a surface facing the X1 direction, and the side surface 534 is a surface facing the X2 direction. A lateral width W3 illustrated in FIG. 3 is a distance between the side surface 533 and the side surface 534, and a height H illustrated in FIG. 4 is a distance between the upper surface 535 and the lower surface 536. As illustrated in FIG. 3, the lateral width W3 of the support 53 is equal to the lateral width W1 of the recess 25 (W3 ≈ W1). As illustrated in FIG. 4, the height H of support 53 is equal to a depth D of the recess 25 (H ≈ D).

Note that in the present description, the expression that the dimension a and the dimension b are “equal” (a ≈ b) includes not only a case in which the dimension a and the dimension b are exactly the same, but also a case in which the dimension a and the dimension b are substantially the same. The “case in which the dimension a and the dimension b are substantially the same” is, for example, a case in which a difference between the dimension a and the dimension b is within a range of manufacturing error. Specifically, when an error of the dimension b with respect to the dimension a is 90% or more and 110% or less (more preferably, 95% or more and 105% or less), the dimension a and the dimension b are interpreted as being “equal”.

The support 53 is fixed to the housing portion 23 in a state of being accommodated in the recess 25 of the housing portion 23. Since the lateral width W3 of the support 53 is equal to the lateral width W1 of the recess 25, the side surface 533 of the support 53 comes into contact with the side surface 251 of the recess 25, and the side surface 534 of the support 53 comes into contact with the side surface 252 of the recess 25. Furthermore, the lower surface 536 of the support 53 is in contact with bottom surface 253 of recess 25. Since the height H of the support 53 is equal to the depth D of the recess 25, the upper surface 535 of the support 53 and the upper surface of the housing portion 23 are continuous without a step. In addition, in a state in which the support 53 is accommodated in the recess 25, the inner wall surface 531 of the support 53 and the inner wall surface of the housing portion 23 are continuous without a step, and the outer wall surface 532 of the support 53 and the outer wall surface of the housing portion 23 are continuous without a step. The support 53 and the housing portion 23 are joined to each other by an appropriate technique such as welding using a laser or adhesion using an adhesive. However, the support 53 may be fixed to the housing portion 23 by fitting the support 53 into the recess 25. That is, the support 53 and the housing portion 23 are not required to be joined to each other.

Not that in the present description, the expression that the surface a and the surface b are “continuous without a step” includes not only a case in which the surface a and the surface b are located completely in the same plane, but also a case in which the surface a and the surface b are located substantially in the same plane. The “case in which the surface a and the surface b are located substantially in the same plane” is, for example, a case in which a step between the surface a and the surface b is within a range of manufacturing error. Specifically, when a step due to a dimensional error within a range of ± 10% (more preferably ± 5%) exists between the surface a and the surface b, the surface a and the surface b are interpreted as “being continuous without a step”. The configuration in which the surface a and the surface b are continuous without a step provides an advantage in that damage due to stress concentration or insufficient rigidity of the step portion can be suppressed. In other words, even a case in which an actual step exists between the surface a and the surface b can be interpreted as “continuous without a step” as long as it is within the range in which the effect of suppressing the damage exemplified above is realized.

The terminal portion 55 is formed by laminating a connection terminal 51p, an insulating sheet 52, and a connection terminal 51n. Each connection terminal 51 (51p, 51n) is a thin plate-shaped electrode formed of a low-resistance conductive material such as copper or a copper alloy. The insulating sheet 52 is a thin plate-shaped member formed of an insulating material. For example, insulating paper is suitably used as the insulating sheet 52.

The connection terminal 51p, the insulating sheet 52, and the connection terminal 51n are laminated in the Z2 direction. Specifically, the insulating sheet 52 is interposed between the connection terminal 51p and the connection terminal 51n. The connection terminal 51p is located in the Z1 direction of the insulating sheet 52, and the connection terminal 51n is located in the Z2 direction of the insulating sheet 52. The connection terminal 51p is a positive electrode input terminal (P terminal) for electrically connecting the semiconductor chip 12p externally. The connection terminal 51n is a negative electrode input terminal (N terminal) for electrically connecting the semiconductor chip 12n externally. The connection terminal 51p and the connection terminal 51n are electrically insulated by the insulating sheet 52. As described above, the configuration in which the connection terminal 51p and the connection terminal 51n face each other with the insulating sheet 52 interposed reduces the inductive component associated with the current path of the semiconductor module 100. Note that a mode in which the connection terminal 51p and the connection terminal 51n do not overlap in plan view is also assumed. In the mode in which the connection terminal 51p and the connection terminal 51n do not overlap, the insulating sheet 52 may be omitted.

As illustrated in FIG. 1, the connection terminal 51p includes a main body 511p and an extension 512p. The main body 511p is a portion having a rectangular shape in plan view. The extension 512p is a rectangular portion extending in the Y1 direction from a part of a peripheral edge 513p located in the Y1 direction in the main body 511p. Specifically, the extension 512p extends in the Y1 direction from a portion located in the X1 direction with respect to the reference surface R in the peripheral edge 513p of the main body 511p. The extension 512p is also expressed as a portion having a smaller width than the main body 511p.

Similarly to the connection terminal 51p, the connection terminal 51n includes a main body 511n and an extension 512n. The main body 511n is a portion having a rectangular shape in plan view. The extension 512n is a rectangular portion extending in the Y1 direction from a part of a peripheral edge 513n located in the Y1 direction in the main body 511n. Specifically, the extension 512n extends in the Y1 direction from a portion located in the X2 direction with respect to the reference surface R in the peripheral edge 513n of the main body 511n. The extension 512n is also expressed as a portion having a smaller width than the main body 511n. As understood from the above description, the extension 512p of the connection terminal 51p and the extending 512n of the connection terminal 51n are located on opposite sides of the reference surface R. Note that the connection terminal 51n is an example of a “first terminal”, and the connection terminal 51p is an example of a “second terminal”.

The insulating sheet 52 is formed in a rectangular shape in plan view. A peripheral edge 521 of the insulating sheet 52 located in the Z1 direction is located between the peripheral edge 513p of the main body 511p of the connection terminal 51p and a distal end of the extension 512p, and is located between the peripheral edge 513n of the main body 511n of the connection terminal 51n and a distal end of the extension 512n. Therefore, as illustrated in FIG. 3, a portion (hereinafter, referred to as a “join”) 514p including the distal end of the extension 512p of the connection terminal 51p and a portion (hereinafter, referred to as a “join”) 514n including the distal end of the extension 512n of the connection terminal 51n extend in the Y1 direction from the peripheral edge 521 of the insulating sheet 52.

As understood from the above description, the main body 511p and the main body 511n overlap each other in plan view. On the other hand, the join 514p (extension 512p) and the join 514n (extension 512n) do not overlap each other in plan view. Then, the insulating sheet 52 is positioned between the main body 511p and the main body 511n, and does not overlap the join 514p and the join 514n in plan view. According to the above configuration, due to the overlap between the main body 511p and the main body 511n, the inductive component of the current path of the semiconductor module 100 is reduced as described above, and due to the configuration in which the join 514p and the join 514n do not overlap each other, electrical insulation between the join 514p and the join 514n can be reliably secured.

Note that the positions along the Y axis may coincide among the peripheral edge 513p of the connection terminal 51p, the peripheral edge 513n of the connection terminal 51n, and the peripheral edge 521 of the insulating sheet 52. That is, a configuration in which the join 514p is directly connected to the main body 511p and the join 514n is directly connected to the main body 511n is also assumed. In other words, a portion of the extension 512p other than the join 514p may be omitted from the connection terminal 51p, and a portion of the extension 512n other than the join 514n may be omitted from the connection terminal 51n. Note that the main body 511n is an example of a “first main body”, and the join 514n is an example of a “first join”. In addition, the main body 511p is an example of a “second main body”, and the join 514p is an example of a “second join”.

The terminal portion 55 penetrates the support 53 along the Y axis. A portion of the connection terminal 51p close to the peripheral edge 513p of the main body 511p and all the extension 512p extend from the inner wall surface 531 of the support 53 in the Y1 direction. Similarly, a portion of the connection terminal 51n close to the peripheral edge 513n of the main body 511n and all the extension 512n extend from the inner wall surface 531 of the support 53 in the Y1 direction.

As illustrated in FIG. 1, the join 514p of the connection terminal 51p extending in the Y1 direction from the peripheral edge 521 of the insulating sheet 52 overlaps the connection conductor 14p in plan view. The join 514p of the connection terminal 51p is joined to the connection conductor 14p by, for example, laser welding. That is, the connection terminal 51p is electrically connected to the main electrode C of the semiconductor chip 12p via the connection conductor 14p and the conductor pattern 114a.

Similarly, in the connection terminal 51n, the join 514n extending from the peripheral edge 521 of the insulating sheet 52 overlaps the connection conductor 14n in plan view. The join 514n of the connection terminal 51n is joined to the connection conductor 14n by, for example, laser welding. That is, the connection terminal 51n is electrically connected to the main electrode E of the semiconductor chip 12n via the connection conductor 14n, the conductor pattern 114b, and the wiring portion 13n.

The connection unit 22 includes a connection terminal 61 and a support 63. The support 63 is a structure that supports the connection terminal 61. Similarly to the support 53, the support 63 is formed of various resin materials. In a more preferred aspect, the support 63 is formed of the same type of material as that of the housing portion 23. Note that similar to the inner wall surface of the housing portion 23, a base film (not shown) is formed on the inner wall surface of the support 63.

The connection terminal 61 penetrates the support 63 along the Y axis. The connection unit 22 is integrally formed by, for example, insert molding. The support 63 is fixed to the housing portion 23 in a state of being accommodated in the recess 26 of the housing portion 23. A portion of the connection terminal 61 extending from the inner wall surface of the support 63 is joined to the top surface of the connection conductor 14o. That is, the connection terminal 61 is electrically connected to the main electrode E of the semiconductor chip 12p via the connection conductor 14o, the conductor pattern 114c, and the wiring portion 13p, and is electrically connected to the main electrode C of the semiconductor chip 12n via the connection conductor 14o and the conductor pattern 114c.

As understood from the above description, the support 53 (connection unit 21) and the support 63 (connection unit 22) configured separately from housing portion 23 are fixed to the housing portion 23, whereby a rectangular frame-shaped resin case is configured.

As illustrated in FIG. 2, the sealing portion 40 is formed by laminating a sealing material 41 and a sealing material 42. That is, the sealing material 41 is positioned between the laminated substrate 11 of the semiconductor unit 10 and the sealing material 42. The sealing material 41 and the sealing material 42 are formed of, for example, various resin materials such as an epoxy resin. Note that the sealing material 41 and the sealing material 42 may be formed of different materials. For example, the sealing material 41 may be formed of a gel material such as silicone gel, and the sealing material 42 may be formed of an epoxy resin.

The sealing material 41 is filled in the space surrounded by the housing portion 23. Specifically, the sealing material 41 is filled in a space surrounded by the housing portion 23 with the laminated substrate 11 as a bottom surface. Therefore, the sealing material 41 comes into contact with the base film 24 formed on the inner wall surface of the housing portion 23. In addition, a surface F1 of the sealing material 41 is at a position lower than the bottom surface 253 of the recess 25 and the bottom surface 263 of the recess 26 in the housing portion 23. Note that the surface F1 of the sealing material 41 is also referred to as a boundary surface between the sealing material 41 and the sealing material 42. The sealing material 41 is an example of a “first sealing material”.

As illustrated in FIG. 2, the top surface 141 (141p, 141n) of each connection conductor 14 is located higher than the surface F1 of the sealing material 41. That is, a conductive portion 142 (142p, 142n) which is a part including the top surface 141 of each of the connection conductors 14 protrudes in the Z1 direction from the surface F1 of the sealing material 41. On the other hand, a portion of each of the connection conductors 14 other than the conductive portion 142 and an element (the laminated substrate 11, the semiconductor chip 12p, the semiconductor chip 12n, the wiring portion 13p, and the wiring portion 13n) of the semiconductor unit 10 other than each of the connection conductors 14 are at a position lower than the surface F1 of the sealing material 41. That is, in the semiconductor unit 10, only the conductive portion 142 of each connection conductor 14 is exposed from the surface F1 of the sealing material 41, and a portion other than the conductive portion 142 is covered with the sealing material 41. The connection conductor 14n is an example of a “first connection conductor”, and the conductive portion 142n is an example of a “first conductive portion”. In addition, the connection conductor 14p is an example of a “second connection conductor”, and the conductive portion 142p is an example of a “second conductive portion”.

The sealing material 42 is filled in a space surrounded by the housing portion 23, the support 53, and the support 63. Specifically, the sealing material 42 is filled in a space surrounded by the housing portion 23, the support 53, and the support 63 with the surface F1 of the sealing material 41 as a bottom surface. Therefore, the sealing material 42 comes into contact with the base film 24 formed on the inner wall surface of the housing portion 23. A surface F2 of the sealing material 42 is at a position higher than the uppermost surface of the terminal portion 55 (specifically, the upper surface of the connection terminal 51p). That is, the conductive portion 142 of each of the connection conductors 14 (14p, 14n, 14o) exposed from the surface F1 of the sealing material 41, a portion of the terminal portion 55 extending from the inner wall surface 531 of the support 53, and a portion of the connection terminal 61 extending from the inner wall surface of the support 63 are covered with the sealing material 42. Note that the surface F2 of the sealing material 42 is at a position lower than the upper surface of the housing portion 23. The sealing material 42 is an example of a “second sealing material”.

As described above, in the First Embodiment, the connection unit 21 and the connection unit 22 configured separately from the housing portion 23 are fixed to the housing portion 23. Therefore, any of a plurality of types of connection units 21 having different structures may be selectively fixed to the housing portion 23. Similarly, any of a plurality of types of connection units 22 having different structures may be selectively fixed to the housing portion 23. That is, by changing the connection unit 21 or the connection unit 22 installed in the housing portion 23, the semiconductor unit 10 and the housing portion 23 can be shared by different types of semiconductor modules 100.

### A-2: Method for Manufacturing Semiconductor Module 100

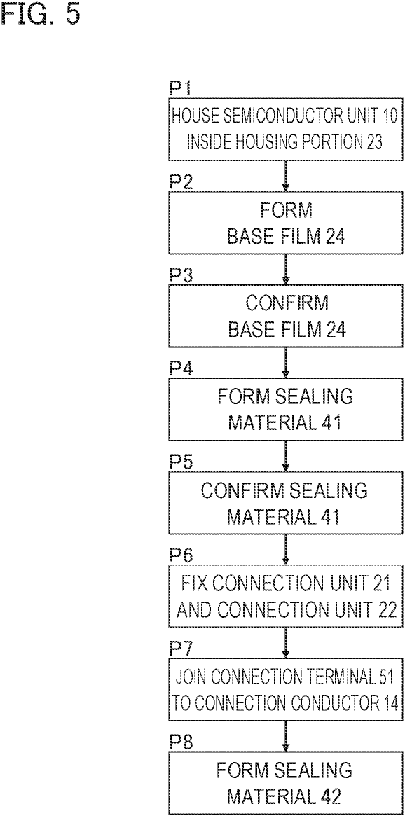

FIG. 5 is a process diagram illustrating a method for manufacturing the semiconductor module 100 described above. First, in step P1 after manufacturing the semiconductor unit 10, the semiconductor unit 10 is disposed inside the housing portion 23. That is, each semiconductor chip 12 (12p, 12n) and at least a part of each connection conductor 14 (14p, 14n, 14o) are surrounded by the housing portion 23. In step P2 after the execution of step P1, the base film 24 is formed on the inner wall surface of the housing portion 23. Specifically, in step P2, a resin material suitable for the base film 24 is applied to the inner wall surface of the housing portion 23, and the resin material is cured to form the base film 24. Step P2 is an example of “forming a base film”.

In step P3 after the execution of step P2, the state of the base film 24 is confirmed. Specifically, it is confirmed whether or not the base film 24 is appropriately formed. For example, an operator visually confirms a state of the base film 24 vertically from above. For example, it is confirmed whether or not the base film 24 is uniformly applied, and whether or not a defect such as damage occurs in the base film 24. Note that the state of the base film 24 may be confirmed by imaging or the like by an imaging device.

When it is confirmed in step P3 that the base film 24 has been properly formed, the sealing material 41 is filled in the space inside the housing portion 23 in step P4. Specifically, the space inside the housing portion 23 is filled with a liquid resin material (for example, epoxy resin), and the resin material is cured by heating or the like to form the sealing material 41. The sealing material 41 is filled up to a position lower than the bottom surface 253 of the recess 25 and the bottom surface 263 of the recess 26 in the housing portion 23. Therefore, the probability that the resin material to be the sealing material 41 will pass through the recess 25 or the recess 26 to leak out is reduced. Immediately after step P4 is executed, as illustrated in FIG. 4, the conductive portion 142 including the top surface 141 of each of the connection conductors 14 (14p, 14n, 14o) is exposed from the surface F1 of the sealing material 41. Note that step P4 is an example of “filling with a first sealing material”.

In step P5 after the execution of step P4, a state of the sealing material 41 is confirmed. Specifically, it is confirmed whether or not the sealing material 41 is appropriately formed. For example, an operator visually confirms a state of the sealing material 41 vertically from above. For example, it is confirmed whether or not the sealing material 41 sufficiently adheres to the base film 24, and whether or not a defect such as an air bubble or an unfilled portion is generated in the sealing material 41. Note that a state of the sealing material 41 may be confirmed by imaging by an imaging device.

In step P6 after the execution of step P5, the connection unit 21 and the connection unit 22 are fixed to the housing portion 23. That is, in the First Embodiment, the connection unit 21 and the connection unit 22 are installed in the housing portion 23 after the formation and confirmation of the base film 24 and the sealing material 41. Specifically, the support 53 of the connection unit 21 is accommodated and fixed in the recess 25 of the housing portion 23, and the support 63 of the connection unit 22 is accommodated and fixed in the recess 26 of the housing portion 23. In a stage in which step P6 is executed, as illustrated in FIG. 1, the join 514p of the connection terminal 51p overlaps the connection conductor 14p in plan view, and the join 514n of the connection terminal 51n overlaps the connection conductor 14n in plan view. As described above, in the First Embodiment, by accommodating the support 53 in the recess 25 of the housing portion 23, the position of the support 53 is determined with respect to the housing portion 23 along the X-axis. Therefore, the work of fixing the connection unit 21 to the housing portion 23 is simplified as compared with a mode in which the position of the support 53 with respect to the housing portion 23 needs to be adjusted separately from the fixing of the support 53 with respect to the housing portion 23. The same applies to the connection unit 22.

The connection unit 21 of the First Embodiment includes the connection terminal 51p and the connection terminal 51n. Therefore, the work of step P6 of installing the connection terminal 51p and the connection terminal 51n in the housing portion 23 is simplified as compared with the configuration in which the connection terminal 51p and the connection terminal 51n are installed independently of each other.

As described above, the conductive portion 142p of the connection conductor 14p and the conductive portion 142n of the connection conductor 14n are exposed from the surface F1 of the sealing material 41. In step P7 after the execution of step P6, the join 514p of the connection terminal 51p is joined to the top surface 141p of the conductive portion 142p, and the join 514n of the connection terminal 51n is joined to the top surface 141n of the conductive portion 142n. For example, laser welding is suitably used for joining the joins 514 (514p, 514n) and the conductive portions 142 (142p, 142n). In a stage of step P7, elements of the semiconductor unit 10 other than the conductive portions 142 (142p, 142n) are covered with the sealing material 41. This reduces a probability that foreign matter generated by, for example, laser welding or the like, directly adheres to each element (for example, the semiconductor chip 12 or the like) of the semiconductor unit 10.

As understood from the above description, step P6 and step P7 are steps of fixing the connection unit 21 to the housing portion 23 and joining the conductive portion 142 (142p, 142n) of the connection conductor 14 (14p, 14n) and the connection terminal 51 (51p, 51n) (an example of “joining”). Note that the order of step P6 and step P7 may be reversed. That is, after the connection terminal 51 is joined to the conductive portion 142 of each connection conductor 14 (step P7), the support 53 may be fixed to the housing portion 23 (step P6).

In step P8 after the execution of step P7, a space surrounded by the housing portion 23, the support 53, and the support 63 is filled with the sealing material 42. Specifically, it is filled with a liquid resin material (for example, epoxy resin) constituting the sealing material 42, and the resin material is cured by heating or the like to form the sealing material 42. Note that step P8 is an example of “filling with a second sealing material”.

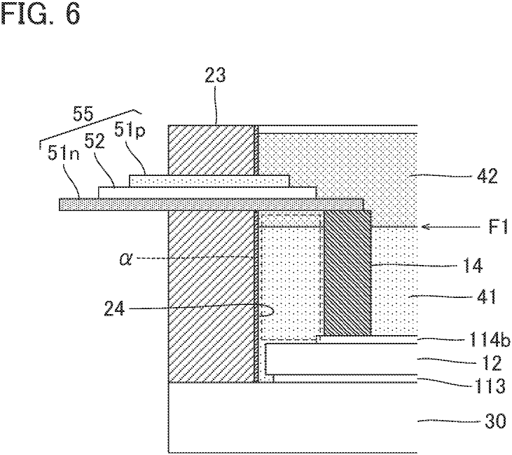

For comparison with the First Embodiment described above, as illustrated in FIG. 6, a configuration in which the terminal portion 55 is directly installed in the housing portion 23 (hereinafter referred to as “Comparative Example 1”) is assumed. In the First Embodiment, the support 53 on which the terminal portion 55 is installed is configured separately from the housing portion 23, whereas the Comparative Example 1 is a configuration in which the terminal portion 55 is installed in the housing portion 23 constituting the housing body 20. In the Comparative Example 1, in a stage of forming the base film 24 or the sealing material 41, the terminal portion 55 is installed in the housing portion 23. That is, a range α in FIG. 6 located immediately below the terminal portion 55 (Z2 direction) in the space surrounded by the housing portion 23 is located behind the terminal portion 55 as viewed vertically from a point above. Therefore, in the Comparative Example 1, the work of forming the base film 24 and the sealing material 41 and the work of confirming the states of the base film 24 and the sealing material 41 are hindered by the terminal portion 55.

In contrast to the Comparative Example 1, in the First Embodiment, the connection unit 21 is fixed to the housing portion 23 after the formation of the sealing material 41, and the connection terminals 51 (51p, 51n) of the connection unit 21 are joined to the conductive portions 142 (142p, 142n) exposed from the surface F1 of the sealing material 41 in the connection conductors 14 (14p, 14n). That is, the sealing material 41 is formed with the terminal portion 55 not installed in the housing portion 23. Therefore, step P4 of forming the sealing material 41 and step P5 of confirming the state of the sealing material 41 can be easily executed without being disturbed by the terminal portion 55. Furthermore, in the First Embodiment, the base film 24 is formed with the terminal portion 55 not installed in the housing portion 23. Therefore, step P2 of forming the base film 24 on the inner wall surface of the housing portion 23 and step P3 of confirming the state of the base film 24 can be easily executed without being disturbed by the terminal portion 55.

Incidentally, in the process of manufacturing the semiconductor module 100, a test (hereinafter referred to as an “insulation test”) is executed to determine whether or not the connection terminal 51p and the connection terminal 51n are appropriately insulated by the insulating sheet 52. In the Comparative Example 1, since the terminal portion 55 is directly fixed to the housing portion 23, it is necessary to fix all of the housing portion 23 in the test device for the insulation test. Therefore, the problem that the scale of the test device is large is assumed. In contrast to the Comparative Example 1, since the terminal portion 55 is installed in the connection unit 21 separate from the housing portion 23 in the First Embodiment, the connection unit 21 may be fixed to the test device in the insulation test. That is, according to the First Embodiment, there is also an effect that the scale of the test device used for the insulation test can be reduced.

### B: Second Embodiment

A Second Embodiment will be described below. Note that, for elements having functions similar to those of the First Embodiment in each configuration exemplified below, the reference numerals used in the description of the First Embodiment are used, and detailed description of each element is omitted as appropriate.

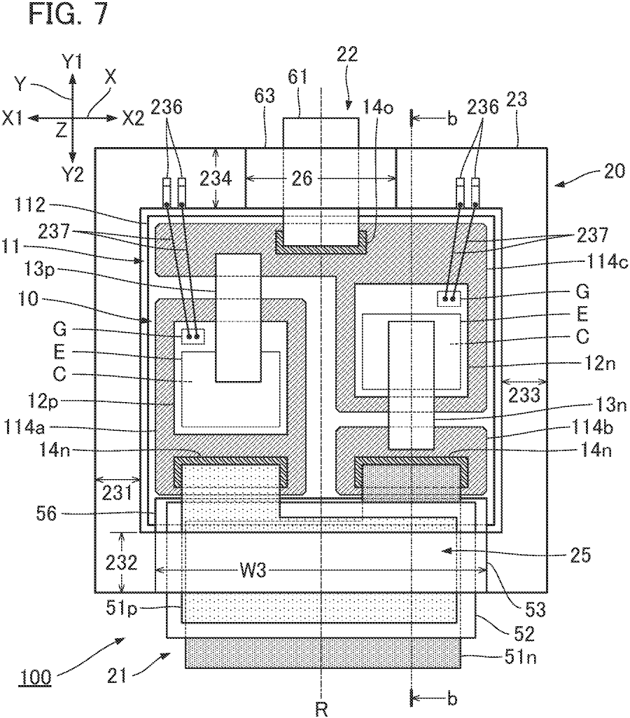

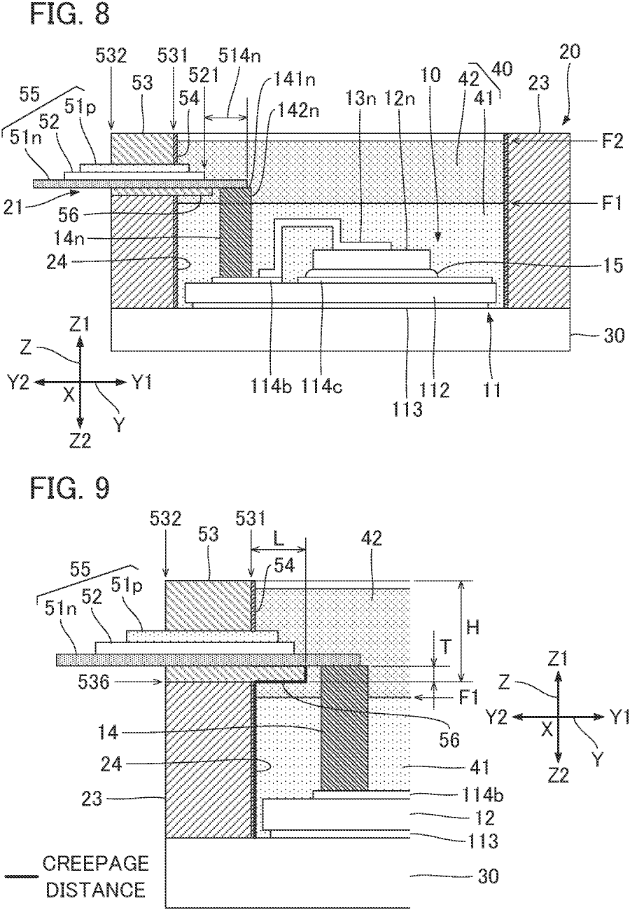

FIG. 7 is a plan view illustrating a configuration of a semiconductor module 100 according to the Second Embodiment. FIG. 8 is a cross-sectional view taken along line b-b in FIG. 7. The semiconductor module 100 of the Second Embodiment has a configuration in which a protrusion 56 is added to the support 53 of the connection unit 21 in the First Embodiment. The configuration other than the protrusion 56 is the same as that of the First Embodiment. The semiconductor module 100 of the Second Embodiment is manufactured by the manufacturing method described above with reference to FIG. 5. Therefore, the Second Embodiment also realizes the same effects as those of the First Embodiment.

FIG. 9 is an enlarged cross-sectional view of the vicinity of the protrusion 56. As illustrated in FIGS. 7 to 9, the protrusion 56 is an eave-like portion protruding in the Y1 direction from the inner wall surface 531 of the support 53, and is formed integrally with the support 53 by, for example, insert molding. As illustrated in FIG. 7, the protrusion 56 extends along the X axis over all the width W3 of the support 53. As illustrated in FIG. 9, a thickness T of the protrusion 56 is sufficiently less than a height H of the support 53. In addition, a length L of the protrusion 56 in the direction (that is, the Y1 direction) in which the protrusion 56 protrudes from the inner wall surface 531 of the support 53 exceeds the thickness T of the protrusion 56 (L > T). That is, the protrusion 56 is formed in a flat plate shape parallel to the XY plane. Note that in FIG. 6, the mode in which the base film 54 covers the inner wall surface 531 of the support 53 is exemplified, but the base film 54 may also cover the protrusion 56 in addition to the inner wall surface 531.

The upper surface of the protrusion 56 is in contact with the lower surface of the connection terminal 51n (that is, the lowermost surface of the terminal portion 55). That is, the protrusion 56 is located between the connection terminal 51n and the sealing material 41 (also between the connection terminal 51n and the base portion 30). Specifically, a space is formed between the lower surface of the protrusion 56 and the surface F1 of the sealing material 41, and the space is filled with the sealing material 42. That is, the lower surface of the protrusion 56 faces the surface F1 of the sealing material 41 with the sealing material 42 interposed. In addition, the lower surface of the protrusion 56 and the lower surface 536 of the support 53 are located in the same plane. That is, the lower surface of the protrusion 56 and the lower surface 536 of the support 53 are continuous without a step.

The tip of the protrusion 56 (that is, the end in the Y1 direction) faces the side surface of each of the connection conductor 14p and the connection conductor 14n at an interval. Specifically, a distance between the tip of the protrusion 56 and the side surface of each connection conductor 14 (14p, 14n) exceeds 1 mm. That is, even assuming that the tip of the protrusion 56 and the side surface of the connection conductor 14 face each other with a gap therebetween, a creepage distance passing through the gap is not formed.

FIG. 10 is an enlarged cross-sectional view of the vicinity of the support 53 in the First Embodiment. There is a case in which the sealing material 41 peels off from the base film 24 (or the inner wall surface of the housing portion 23) due to residual stress in the housing portion 23 or the sealing material 41, thermal stress caused by a difference in linear expansion coefficient between the housing portion 23 and the sealing material 41, or the like. In the First Embodiment, when a portion of the sealing material 41 located immediately below the terminal portion 55 peels off from the base film 24, the distance between the lower surface of the connection terminal 51n and the surface of the base portion 30 is a creepage distance as illustrated by a thick line in FIG. 10.

In the Second Embodiment, the protrusion 56 in contact with the lower surface of the connection terminal 51n protrudes from the inner wall surface 531 of the support 53. Therefore, when the sealing material 41 peels off from the base film 24 (the inner wall surface of the housing portion 23), a creepage distance between the connection terminal 51n and the base portion 30 is the sum of the height of the housing portion 23, the length L of the protrusion 56, and the thickness T of the protrusion 56, as shown by a thick line in FIG. 9. As understood from the above description, according to the Second Embodiment, it is easy to secure the creepage distance immediately below the terminal portion 55 as compared with the First Embodiment in which the protrusion 56 is not formed. That is, there is an advantage in that the insulation property of the terminal portion 55 of the connection unit 21 can be easily secured. In the Second Embodiment, in particular, the length L of the protrusion 56 exceeds the thickness T of the protrusion 56. Therefore, as compared with a mode in which the length L of the protrusion 56 is smaller than the thickness T of the protrusion 56, the creepage distance can be sufficiently secured when the sealing material 41 peels off from the base film 24.

Note that in the Comparative Example 1 in which the terminal portion 55 is installed in the housing portion 23, a configuration in which the protrusion 56 is formed on the inner wall surface of the housing portion 23 (hereinafter referred to as “Comparative Example 2”) is assumed. However, in the Comparative Example 2, the inner wall surface of the side wall 232 of the housing portion 23 is located behind both the terminal portion 55 and the protrusion 56. Therefore, in the Comparative Example 2, the problem that the formation and confirmation of the base film 24 and the confirmation of the sealing material 41 are hindered becomes more apparent than in Comparative Example 1. In contrast to the Comparative Example 2, the protrusion 56 is formed on the support 53 separate from the housing portion 23, in the Second Embodiment. That is, the base film 24 and the sealing material 41 are formed without the terminal portion 55 and the protrusion 56. Therefore, step P2 of forming the base film 24 on the inner wall surface of the housing portion 23, step P3 of confirming the state of the base film 24, and step P5 of confirming the state of the sealing material 41 can be easily executed without being disturbed by any of the terminal portion 55 and the protrusion 56. That is, the configuration in which the support 53 is formed separately from the housing portion 23 is particularly effective for the configuration in which the protrusion 56 is formed on the support 53.

### C: Third Embodiment

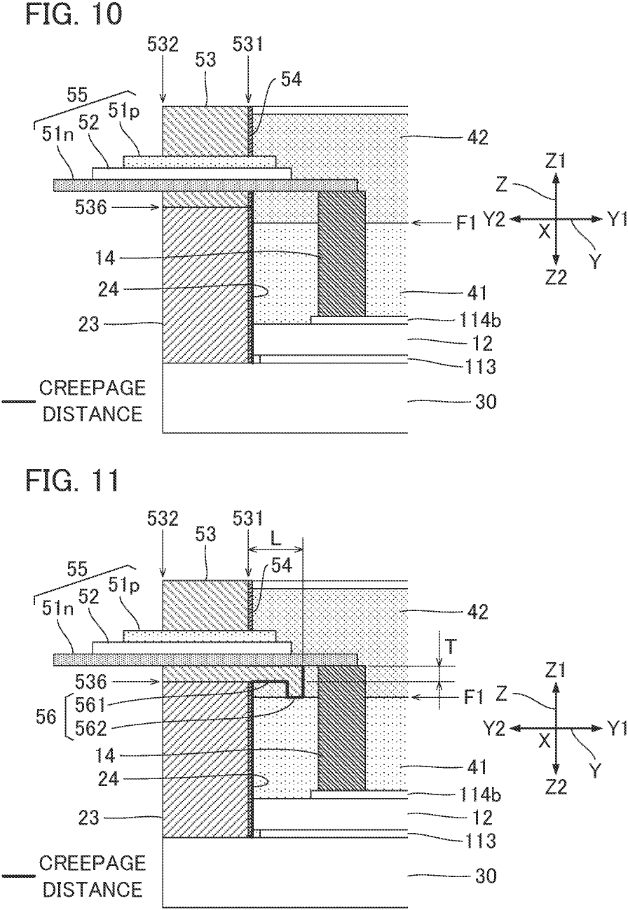

FIG. 11 is a partial cross-sectional view of a semiconductor module 100 according to a Third Embodiment. Similarly to the Second Embodiment, the semiconductor module 100 according to the Third Embodiment includes a protrusion 56 protruding in the Y1 direction from the inner wall surface 531 of the support 53. Similarly to FIG. 9 described above, FIG. 11 illustrates the vicinity of the protrusion 56. Note that the configuration other than the protrusion 56 is the same as that of the First Embodiment. In addition, the semiconductor module 100 of the Third Embodiment is manufactured by the manufacturing method described above with reference to FIG. 5. Therefore, the Third Embodiment also realizes the same effects as those of the First Embodiment.

The protrusion 56 of the Third Embodiment extends along the X axis over all the width W3 of the support 53, similarly to the protrusion 56 of the Second Embodiment. The protrusion 56 is integrally formed with the support 53 by, for example, insert molding. As illustrated in FIG. 11, the protrusion 56 of the Third Embodiment includes a first portion 561 and a second portion 562.

Similarly to the protrusion 56 of the Second Embodiment, the first portion 561 is an eave-like portion protruding in the Y1 direction from the inner wall surface 531 of the support 53. A length L of the first portion 561 in the Y1 direction exceeds the thickness T of the first portion 561 (L > T). That is, the first portion 561 is formed in a flat plate shape parallel to the XY plane. The second portion 562 is a portion protruding from a distal end of the first portion 561 in the Y1 direction toward a side opposite to the connection terminals 51 (51p, 51n) (that is, the Z2 direction). A tip of the second portion 562 (that is, an end opposite to the first portion 561) contacts the surface F1 of the sealing material 41. As in the Second Embodiment, a predetermined interval is secured between the protrusion 56 and the connection conductors 14 (14p, 14n) of the Second Embodiment.

As described above, in the Third Embodiment, the protrusion 56 includes, in addition to the first portion 561 protruding from the inner wall surface 531 of the support 53, the second portion 562 protruding from the distal end of the first portion 561 to the side opposite to the connection terminals 51 (51p, 51n). Therefore, as illustrated in FIG. 11, as compared with the Second Embodiment in which the protrusion 56 is formed in a simple flat plate shape, a creepage distance between the connection terminal 51n and the base portion 30 can be sufficiently secured. In addition, in the Third Embodiment, the tip of the second portion 562 comes into contact with the surface F1 of the sealing material 41. Therefore, as compared with the configuration in which the tip of the second portion 562 is not in contact with the surface F1 of the sealing material 41, it is possible to stabilize the orientation of the connection unit 21 in the above-described step P6 of fixing the connection unit 21 to the housing portion 23. However, a mode in which the tip of the second portion 562 is not in contact with the surface F1 of the sealing material 41 is also assumed.

### D: Fourth Embodiment

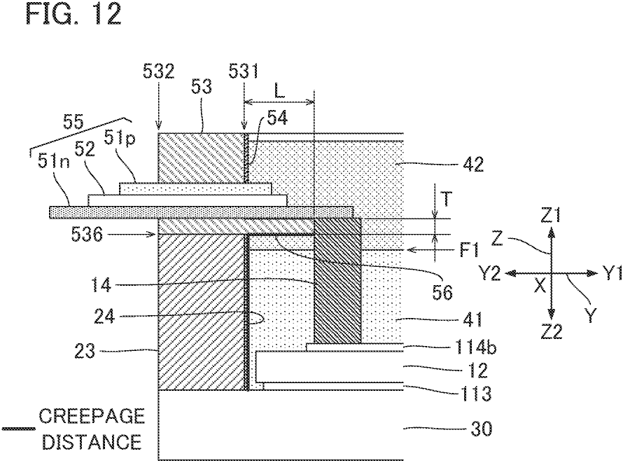

FIG. 12 is a partial cross-sectional view of a semiconductor module 100 according to a Fourth Embodiment. Similarly to the Second Embodiment, the semiconductor module 100 of the Fourth Embodiment includes a protrusion 56 protruding in the Y1 direction from the inner wall surface 531 of the support 53. Similarly to FIG. 9 described above, FIG. 12 illustrates the vicinity of the protrusion 56. Note that the configuration of other than that of the protrusion 56 is the same as that of the First Embodiment. In addition, the semiconductor module 100 of the Fourth Embodiment is manufactured by the manufacturing method described above with reference to FIG. 5. Therefore, the Fourth Embodiment also realizes the same effects as those of the First Embodiment.

As illustrated in FIG. 12, the protrusion 56 of the Fourth Embodiment is, similarly to the protrusion 56 of the Second Embodiment, an eave-like portion protruding in the Y1 direction from the inner wall surface 531 of the support 53, and is formed integrally with the support 53 by, for example, insert molding. The protrusion 56 extends along the X axis over all the width W3 of the support 53.

In the Second Embodiment, the configuration in which the tip of the protrusion 56 faces the side surface of each connection conductor 14 (14p, 14n) at an interval has been exemplified. In the Fourth Embodiment, the tip of the protrusion 56 comes into contact with the side surface of each connection conductor 14 (14p, 14n) as illustrated in FIG. 12. That is, a length L of the protrusion 56 is substantially equal to the distance between the inner peripheral surface of the housing portion 23 and the side surface of each connection conductor 14. The configuration in which the length L of the protrusion 56 exceeds a thickness T of the protrusion 56 is similar to that of the Second Embodiment. That is, the protrusion 56 is formed in a flat plate shape parallel to the XY plane.

In the Fourth Embodiment, when the sealing material 41 peels off from the base film 24 (an inner wall surface of the housing portion 23), a creepage distance between the connection terminal 51n and the base portion 30 is the sum of a height of the housing portion 23 and the length L of the protrusion 56. That is, according to the Fourth Embodiment, similarly to the Second Embodiment, there is an advantage in that the creepage distance immediately below the terminal portion 55 is easily secured as compared with the First Embodiment in which the protrusion 56 is not formed.

In step P6 of fixing the connection unit 21 to the housing portion 23 in the method for manufacturing the semiconductor module 100 according to the Fourth Embodiment, the connection unit 21 arranged inside the recess 25 is moved in the Y1 direction until the tip of the protrusion 56 abuts on the side surface of each connection conductor 14 (14p, 14n). Then, the support 53 is fixed to the housing portion 23 with the tip of the protrusion 56 abutting on the side surface of each connection conductor 14. As understood from the above description, in the Fourth Embodiment, the position of the connection unit 21 in the Y1 direction can be determined by bringing the tip of the protrusion 56 into contact with the side surface of each connection conductor 14. That is, the protrusion 56 can be used for positioning the connection terminals 51 (51p, 51n) with respect to each connection conductor 14. On the other hand, according to the Second Embodiment in which the tip of the protrusion 56 faces the side surface of the connection conductor 14 at an interval, there is an advantage in that it is easy to secure the creepage distance between the connection terminal 51n and the base portion 30 as compared with the Fourth Embodiment.

Note that in the Third Embodiment in which the protrusion 56 includes the first portion 561 and the second portion 562, similarly to the Fourth Embodiment, the protrusion 56 may be brought into contact with the side surface of each connection conductor 14 (14p, 14n). Specifically, the surface in the Y1 direction (that is, the surface facing each of the connection conductors 14) of the second portion 562 of the protrusion 56 in FIG. 11 comes into contact with the side surface of each of the connection conductors 14. The above configuration realizes effects similar to those of the Third Embodiment.

### E: Modifications

A specific modification added to each aspect exemplified above will be exemplified below. Two or more aspects randomly selected from the following examples may be combined as appropriate within a range in which they do not conflict with each other.

(1) In the First Embodiment, the configuration in which the conductive portion 142 of each connection conductor 14 (14p, 14n, 14o) is exposed from the surface F1 of the sealing material 41 (hereinafter referred to as “Configuration 1”) and the configuration in which the connection unit 21 separate from the housing portion 23 is fixed to the housing portion 23 (hereinafter referred to as “Configuration 2”) have been exemplified. Furthermore, in the Second to Fourth Embodiments, the configuration in which the protrusion 56 protrudes from the inner wall surface 531 of the support 53 (hereinafter referred to as “Configuration 3”) has been exemplified. The First Embodiment corresponds to a combination of the Configuration 1 and the Configuration 2, and the Second Embodiment to the Fourth Embodiment correspond to a combination of the Configuration 1 to the Configuration 3. As exemplified below, the combination of the Configurations 1 to 3 is not limited to the above-described exemplification. That is, two or more configurations freely selected from the Configurations 1 to 3 can be combined.

### Aspect A

For example, the aspect A illustrated in FIG. 13 is a mode in which the configuration 1 and the configuration 3 are combined. In the aspect A, a terminal portion 55 is installed in a single housing portion 23 having a rectangular frame shape. Each connection terminal 51 (14p, 14n) of the terminal portion 55 is joined to the conductive portion 142 exposed from the surface F1 of the sealing material 41 among the connection conductors 14 (51p, 51n) (Configuration 1). Furthermore, a protrusion 56 protruding in the Y1 direction from the inner wall surface of the housing portion 23 is formed in the housing portion 23 (Configuration 3). As understood from the above description, the Configuration 2 is omitted in the aspect A. Note that the protrusion 56 in FIG. 13 may be replaced with the protrusion 56 exemplified in the Third Embodiment or the Fourth Embodiment.

### Aspect B

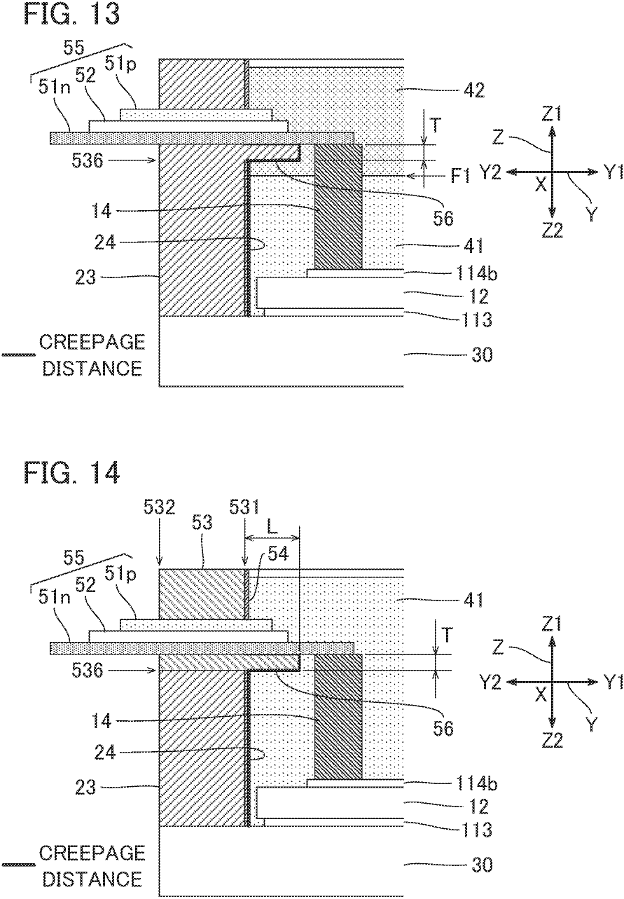

The aspect B illustrated in FIG. 14 is a mode in which the Configuration 2 and the Configuration 3 are combined. In the aspect B, the connection unit 21 separate from the housing portion 23 is fixed to the housing portion 23 (Configuration 2). Each connection terminal 51 (51p, 51n) of the terminal portion 55 installed in the connection unit 21 is joined to the top surface 141 of each connection conductor 14 (14p, 14n). Furthermore, a protrusion 56 protruding in the Y1 direction from the inner wall surface 531 of the support 53 of the connection unit 21 is formed in the housing portion 23 (Configuration 3). On the other hand, the sealing material 41 is formed so as to cover all of the semiconductor unit 10 including the top surface 141 of each connection conductor 14. That is, in the aspect B, the configuration 1 is omitted. Note that the protrusion 56 in FIG. 14 may be replaced with the protrusion 56 of the Third Embodiment or the Fourth Embodiment.

(2) A mode including each of the above-described Configurations 1 to 3 alone is also assumed. For example, the mode illustrated in FIG. 15 (hereinafter referred to as “aspect C”) is a mode including only the Configuration 3 among the Configurations 1 to 3. In the aspect C, a protrusion 56 protruding in the Y1 direction from the inner wall surface of the housing portion 23 is formed in the housing portion 23 (configuration 3). The terminal portion 55 is installed in the housing portion 23, and the sealing material 41 is formed so as to cover all of the semiconductor unit 10 including the top surface 141 of each connection conductor 14. That is, the Configuration 1 and the Configuration 2 are omitted. Note that the protrusion 56 in FIG. 15 may be replaced with the protrusion 56 of the Third Embodiment or the Fourth Embodiment. As understood from the above description, regardless of the presence or absence of the Configuration 1 and the Configuration 2, the Configuration 3 realizes the effect of easily securing the creepage distance of the connection terminal 51n as compared with the configuration in which the protrusion 56 is not formed. Note that the aspect C in FIG. 15 corresponds to the above-described Comparative Example 2. In addition, in the aspect C (Configuration 3), the sealing portion 40 (the sealing material 41 and the sealing material 42) may be omitted.

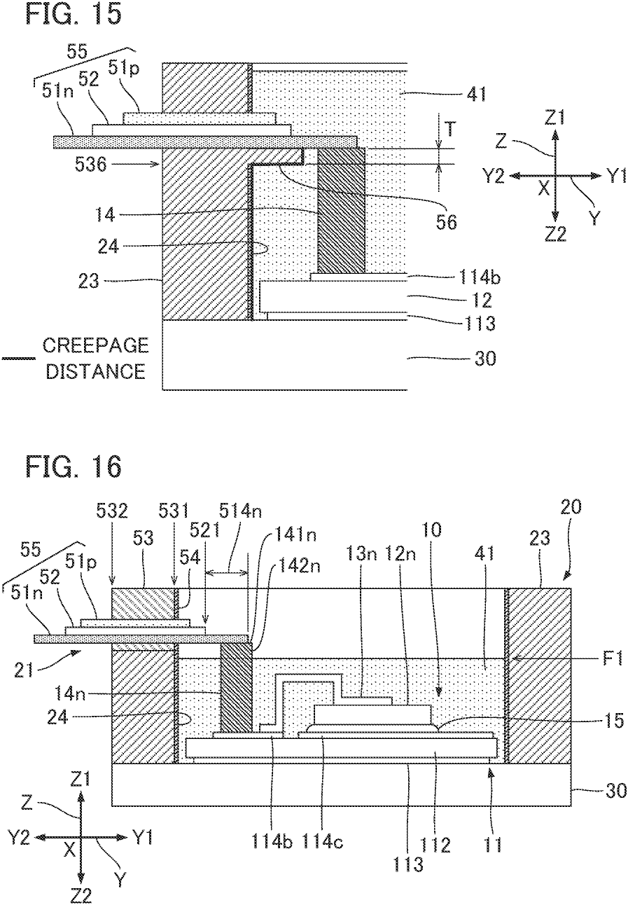

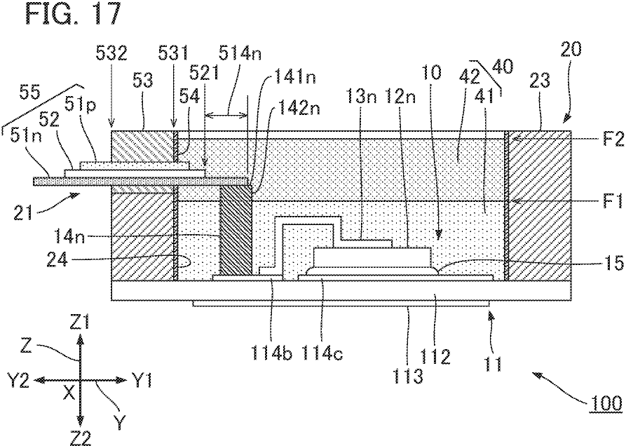

(3) In each of the above-described embodiments, the configuration in which the sealing portion 40 includes the sealing material 41 and the sealing material 42 has been exemplified, but as illustrated in FIG. 16, the sealing material 42 may be omitted. That is, the sealing portion 40 may be formed only of the sealing material 41. Note that the configuration in which the terminal portion 55 is sealed by the sealing portion 40 has an advantage in that the insulation property of the connection terminal 51 (51p, 51n) can be easily secured. In the configuration in which the conductive portion 142 of the connection conductors 14 (14p, 14n) is exposed from the surface F1 of the sealing material 41, in particular, by forming the sealing material 42, the insulation property of the connection conductor 14 can be sufficiently secured.

(4) In each of the above-described embodiments, the configuration in which the base film 24 is formed on the inner wall surface of the housing portion 23 has been exemplified, but the base film 24 may be omitted. Note that the Configuration 2 described above can form the base film 24 with the terminal portion 55 not installed in the housing portion 23. Therefore, step P2 of forming the base film 24 on the inner wall surface of the housing portion 23 and step P3 of confirming the state of the base film 24 can be easily executed without being disturbed by the terminal portion 55. From the above viewpoint, the Configuration 2 is particularly effective for a configuration in which the base film 24 is formed on the inner peripheral surface of the housing portion 23.

(5) In each of the above-described embodiments, the configuration in which the semiconductor unit 10 is housed in the space surrounded by the housing body 20 with the base portion 30 as a bottom surface has been exemplified, but the base portion 30 is not an essential element for the semiconductor module 100. For example, as illustrated in FIG. 17, a configuration not requiring the base portion 30 is also assumed.

In the configuration of FIG. 17, the insulating substrate 112 of the laminated substrate 11 and the housing portion 23 are joined to each other, so that the semiconductor unit 10 is supported by the housing body 20. Specifically, an edge of the upper surface of the insulating substrate 112 and the lower surface of the housing portion 23 are joined by, for example, an adhesive. In the configuration of FIG. 17, the insulating substrate 112 and the metal layer 113 are located in the Z2 direction with respect to the lower surface of the housing portion 23. That is, a part of the semiconductor unit 10 is located outside the space surrounded by the housing portion 23. On the other hand, in each of the above-described embodiments, all of the semiconductor unit 10 is surrounded by the housing portion 23 (housing body 20). As understood from the above examples, the housing body 20 is comprehensively expressed as an element surrounding the semiconductor chip 12, and it does not matter whether it surrounds all or a part of the semiconductor unit 10. Note that the side surface of the insulating substrate 112 and the inner wall surface of the housing portion 23 may be joined by, for example, an adhesive.

In addition, in each of the above-described embodiments, the configuration in which the sealing portion 40 (sealing material 41) is filled up to the space on the side and the lower side of the laminated substrate 11 has been exemplified, but as understood from the example of FIG. 17, a mode in which the sealing portion 40 does not reach the space on the side and the lower side of the laminated substrate 11 is also assumed.

(6) In each of above-described embodiments, the configuration in which the top surface 141 of each connection conductor 14 (14p, 14n) is at a position higher than the bottom surface 253 of the recess 25 has been exemplified. In the above configuration, a part of each connection conductor 14 including the top surface 141 is located outside the space surrounded by the housing portion 23 (at a position higher than the bottom surface 253 of the recess 25). On the other hand, a configuration in which the top surface 141 of each connection conductor 14 (14p, 14n) is at a position lower than the bottom surface 253 of the recess 25 is also assumed. That is, all of the connection conductors 14 may be surrounded by the housing portion 23. As understood from the above description, at least a part of the connection conductor 14 (14p, 14n) is surrounded by the housing portion 23.

(7) In each of the above-described embodiments, the configuration in which the semiconductor chip 12 includes the RC-IGBT has been exemplified, but the configuration of the semiconductor chip 12 is not limited to the above example. For example, a mode in which the semiconductor chip 12 includes an IGBT or a MOSFET is also assumed. In a mode in which the semiconductor chip 12 includes a MOSFET, the main electrode C is one of a source electrode and a drain electrode, and the main electrode E is the other of the source electrode and the drain electrode. In addition, the number of semiconductor chips 12 included in the semiconductor module 100 is not limited to 2. For example, a mode in which the semiconductor module 100 includes one, or three or more, semiconductor chips 12 is also assumed.

### DESCRIPTION OF REFERENCES SIGNS

100... semiconductor module, 10... semiconductor unit, 11... laminated substrate, 112... insulating substrate, 113... metal layer, 114(114a, 114b, 114c)... conductor pattern, 12(12p, 12n)... semiconductor chip, 13(13p, 13n)... wiring portion, 14(14p, 14n, 14o)... connection conductor, 141(141p, 141n)... top surface, 142(142p, 142n)... conductive portion, 15... joining material, 20... housing body, 21, 22... connection unit, 23... housing portion, 24... base film, 25, 26... recess, 251, 252, 261, 262... side surface, 253, 263... bottom surface, 30... base portion, 40... sealing portion, 41... sealing material, 42... sealing material, 51(51p, 51n)... connection terminal, 52... insulating sheet, 53, 63... support, 55... terminal portion, 56... protrusion, 61... connection terminal, 231, 232, 233, 234... side wall, 236... control terminal, 237... wire, 511(511p, 511n)... main body, 512(512p, 512n)... extension, 514(514p, 514n)... join, 561... first portion, 562... second portion.

What is claimed is:

1. A semiconductor module comprising:
a first semiconductor chip including a first main electrode;
a first connection conductor electrically connected to the first main electrode;
a housing portion surrounding the first semiconductor chip and at least a part of the first connection conductor;
a first sealing material filled in a space surrounded by the housing portion; and
a connection unit fixed to the housing portion, wherein
a first conductive portion is exposed from a surface of the first sealing material, the first conductive portion being a part of the first connection conductor, and
the connection unit includes:
a first terminal joined to the first conductive portion of the first connection conductor; and
a support that is configured separately from the housing portion and supports the first terminal.

2. The semiconductor module according to claim 1, wherein
a recess is formed in the housing portion,
the support is accommodated in the recess, and
a surface of the first sealing material is at a position lower than a bottom surface of the recess.

3. The semiconductor module according to claim 1, further comprising a base film that covers an inner wall surface of the housing portion, wherein
the first sealing material is in contact with the base film.

4. The semiconductor module according to claim 1, further comprising a second sealing material filled in a space surrounded by the housing portion and the support.

5. The semiconductor module according to claim 1, further comprising a protrusion that protrudes from an inner wall surface of the support and is in contact with a bottom surface of the first terminal.

6. The semiconductor module according to claim 5, wherein a length of the protrusion in a direction protruding from the inner wall surface of the support exceeds a thickness of the protrusion.

7. The semiconductor module according to claim 5, wherein a tip of the protrusion faces a side surface of the first connection conductor at an interval.

8. The semiconductor module according to claim 5, wherein a tip of the protrusion is in contact with a side surface of the first connection conductor.

9. The semiconductor module according to claims 5, wherein the protrusion includes:
a first portion protruding from the inner wall surface of the support; and
a second portion protruding from a distal end of the first portion to a side opposite to the first terminal.

10. The semiconductor module according to claim 9, wherein a tip of the second portion is in contact with the surface of the first sealing material.

11. The semiconductor module according to claim 1, further comprising a second semiconductor chip that is surrounded by the housing portion and includes a second main electrode, wherein
the connection unit further includes a second terminal supported by the support, and
the second terminal is electrically connected to the second main electrode and is electrically insulated from the first terminal.

12. The semiconductor module according to claim 11, further comprising a second connection conductor electrically connected to the second main electrode, wherein
the housing portion surrounds at least a part of the second connection conductor,
a second conductive portion is exposed from a surface of the first sealing material, the second conductive portion being a part of the second connection conductor, and
the second terminal is joined to the second conductive portion of the second connection conductor.

13. The semiconductor module according to claim 12, wherein
the connection unit further includes an insulating sheet having insulation property,
the first terminal includes a first main body and a first join joined to the first conductive portion,
the second terminal includes a second main body and a second join joined to the second conductive portion,
the first main body and the second main body overlap each other in plan view,
the first join and the second join do not overlap each other in plan view, and
the insulating sheet is positioned between the first main body and the second main body, and does not overlap the first join and the second join in plan view.

14. A method for manufacturing a semiconductor module, the method comprising:
filling with a first sealing material a space inside a housing portion surrounding (i) a first semiconductor chip including a first main electrode and (ii) a first connection conductor electrically connected to the first main electrode such that a first conductive portion that is a part of the first connection conductor is exposed; and
after execution of the filling with the first sealing material, fixing to the housing portion a connection unit including the first terminal and a support supporting the first terminal, and joining the first conductive portion of the first connection conductor and a first terminal.

15. The method for manufacturing a semiconductor module according to claim 14, wherein
a recess is formed in the housing portion,
the joining includes accommodating the support in the recess, and
the filling with the first sealing material includes filling the first sealing material up to a position lower than a bottom surface of the recess.

16. The method for manufacturing a semiconductor module according to claim 14, further comprising, before execution of the filling with the first sealing material, forming a base film covering an inner wall surface of the housing portion.

17. The method for manufacturing a semiconductor module according to claim 14, further comprising, after execution of the joining, filling with a second sealing material a space surrounded by the housing portion and the support.

18. The method for manufacturing a semiconductor module according to claim 14, wherein the connection unit includes a protrusion that protrudes from an inner wall surface of the support and is in contact with a bottom surface of the first terminal.
